(19) United States
(12) Patent Application Publication
(10) Pub. No.: US 2025/0224357 A1
(43) Pub. Date: Jul. 10, 2025

(54) CRACK DETECTION METHOD FOR PIEZOELECTRIC ELEMENT AND CRACK DETECTION DEVICE FOR PIEZOELECTRIC ELEMENT

(71) Applicant: SUNCALL CORPORATION, Kyoto (JP)

(72) Inventor: Takashi Nakagawa, Kyoto (JP)

(21) Appl. No.: 19/090,887

(22) Filed: Mar. 26, 2025

Related U.S. Application Data
(63) Continuation of application No. PCT/JP2024/004962, filed on Feb. 14, 2024.

(30) Foreign Application Priority Data
Mar. 14, 2023 (JP) 2023039382

(51) Int. Cl. G01N 27/04

(52) U.S. Cl. CPC G01N 27/041

(57) ABSTRACT

A crack detection device for a piezoelectric element, capable of reducing the possibility of erroneous detection applies a resonant-frequency voltage to a piezoelectric element using an impedance analyzer. A resistive component of an impedance between a pair of electrodes provided in the piezoelectric element due to the application of the voltage is measured by the impedance analyzer. A calculation unit calculates a determination value with respect to the measured value of the measured resistive component of the impedance. A determination unit takes the calculated determination value into consideration and determines whether a crack has occurred in the piezoelectric element on the basis of a preset threshold.

### FIELD OF THE INVENTION

The present invention relates to a crack detection method for a piezoelectric element and a crack detection device for a piezoelectric element.

### BACKGROUND OF THE INVENTION

In general electronic components using piezoelectric elements as actuators, particularly in HDD suspensions, the risk of cracks occurring in the piezoelectric elements has increased due to the recent demand for thickness reductions. However, the piezoelectric elements mounted on the HDD suspensions are small, and there is a problem that detection of the cracks by optical observation is difficult.

Therefore, to solve such a problem, a technique described in Japanese Patent No. 5489968 (Patent Literature 1) has been proposed.

The invention described in Patent Literature 1 involves applying a resonant-frequency voltage to a piezoelectric element, measuring the dielectric loss tangent between a pair of electrodes due to the application of the voltage, and detecting a crack in the piezoelectric element based on the magnitude of the peak of the dielectric loss tangent at the measured resonant frequency.

### SUMMARY OF THE INVENTION

The foregoing detection method measures the dielectric loss tangent, so that it has a problem that erroneous detection may occur. That is, as exemplified in FIG. 5, the dielectric loss tangent has the characteristic that it changes sharply around the resonant frequency. In FIG. 5, when the dielectric loss tangent is Tan D, the dielectric loss tangent (Tan D) changes sharply around the resonant frequency of 6.9 MHz.

To describe this point in detail, the dielectric loss tangent (Tan D) is expressed as Tan D=R/−X when the impedance Z is given as Z=R+jX. Therefore, at a frequency where the denominator X is close to zero, a slight difference in the X value greatly affects the dielectric loss tangent (Tan D). Thus, as shown in FIG. 5, the dielectric loss tangent (Tan D) changes sharply around the resonant frequency (6.9 MHz is exemplified in FIG. 5).

Accordingly, even a slight deviation in the measurement frequency can dramatically change the peak value to be obtained, making it very difficult to set the threshold value, and this causes a problem that erroneous detection may occur during implementation operation.

Therefore, it is conceivable to measure the resistive component of an impedance between the pair of electrodes instead of the dielectric loss tangent. An example of measuring the resistive component of the impedance is shown in FIG. 6(a). In FIG. 6(a), measurements are performed using micro-PZT (lead zirconate titanate) piezoelectric ceramics as piezoelectric elements.

Thus, when these piezoelectric elements are each used to measure the resistive component of the impedance between the pair of electrodes, as shown in FIG. 6(a), there is a clear difference between a waveform R1 group in which the resistive component of the impedance reaches its peak value (around 250 $2 in the figure) around the resonant frequency of 7.6 MHz and a waveform R2 group in which it does not. That is, the waveform R1 group indicates a group in which no cracks have occurred in the piezoelectric elements, and the waveform R2 group indicates a group in which cracks have occurred in the piezoelectric elements, making it easy to set the threshold value. Therefore, the possibility of erroneous detection can be reduced during implementation operation.

However, when the measurements are performed using milli-PZT piezoelectric ceramics as the piezoelectric elements, waveforms as shown in FIG. 6(b) may be obtained. That is, as shown in FIG. 6(b), there may be no place where a clear difference occurs between the waveform R1 group and the waveform R2 group. At this time, the setting of the threshold value becomes difficult, so that there is a possibility of erroneous detection during implementation operation.

Accordingly, in view of the foregoing problem, an object of the present invention is to provide a crack detection method for a piezoelectric element and a crack detection device for a piezoelectric element that can reduce the possibility of erroneous detection regardless of the type of piezoelectric element.

The foregoing object of the present invention is achieved by the following means. Note that reference signs in an embodiment to be described later are added in parentheses, but the present invention is not limited thereto.

According to an embodiment of the invention, a crack detection method for a piezoelectric element includes steps of applying a resonant-frequency voltage to a piezoelectric element (22), measuring a resistive component of an impedance between a pair of electrodes (22a and 22b) of the piezoelectric element (22) alone due to the application of the voltage, calculating a determination value for a measured value of the measured resistive component of the impedance by using Formula (1) below, and taking the calculated determination value into consideration and determining whether a crack has occurred in the piezoelectric element (22) based on a preset threshold value.

$$P = F ( xi , ai ) \qquad Formula 1$$

Here, P represents the determination value, i represents the number of measurement points, xi represents a measured value at each of the measurement points, ai represents an arbitrarily set coefficient, and F(xi, ai) represents an arbitrary function consisting of xi and ai.

According to an embodiment of the invention, the determination value is calculated using Formula (2) below as the Formula (1) in the crack detection method for the piezoelectric element according to claim 1 described above.

$$F = \sum ( xi * ai ) \qquad Formula 2$$

According to an embodiment of the invention, the determination value is calculated using a sigmoid function expressed by Formula (3) below as the Formula (1) in the crack detection method for the piezoelectric element according to claim 1 described above.

$$F ( bi , xi ) = \frac{1}{1 - {e}^{- \sum bi * xi}} \qquad Formula 3$$

Here, bi represents an arbitrary set coefficient.

According to an embodiment of the invention, a crack detection device for a piezoelectric element includes a voltage application means (impedance analyzer 3) that applies a resonant-frequency voltage to a piezoelectric element (22), a measurement means (impedance analyzer 3) that measures a resistive component of an impedance between a pair of electrodes (22a and 22b) of the piezoelectric element (22) alone due to the application of the voltage, a calculation means (calculation unit 43a) that calculates a determination value for a measured value of the measured resistive component of the impedance by using Formula (4) below, and a determination means (determination unit 43b) that takes the calculated determination value into consideration and determines whether a crack has occurred in the piezoelectric element (22) based on a preset threshold value.

$$P = F ( xi , ai ) \qquad Formula 4$$

Here, P represents the determination value, i represents the number of measurement points, xi represents a measured value at each of the measurement points, ai represents an arbitrarily set coefficient, and F(xi, ai) represents an arbitrary function consisting of xi and ai.

Next, advantageous effects of the present invention will be described with reference signs of the drawings. Note that reference signs in an embodiment to be described later are added in parentheses, but the present invention is not limited thereto.

According to embodiments of the invention, the determination value is calculated using Formula (1) or (4) for the measured value of the resistive component of the impedance, so that the possibility of erroneous detection can be reduced regardless of the type of piezoelectric element.

Formula (2) or Formula (3) can be used as a formula related to Formula (1) or (4), and particularly, the possibility of erroneous detection can be further reduced by using Formula (3).

### BRIEF DESCRIPTION OF DRAWINGS

FIG. 1 is a schematic configuration diagram showing a crack detection device for a piezoelectric element according to an embodiment of the present invention.

FIG. 2 is a waveform diagram in a case where determination values are calculated using the above Formula 2 for measured values shown in FIG. 6(b).

FIG. 3 is a waveform diagram in a case where determination values are calculated using the above Formula 3 for the measured values shown in FIG. 6(b).

FIG. 4 is a waveform diagram showing results of comparing the number of samples used for analysis with the accuracy of detection.

FIG. 5 is a waveform diagram when the dielectric loss tangents between pairs of electrodes at a resonant frequency of piezoelectric elements according to the embodiment are measured.

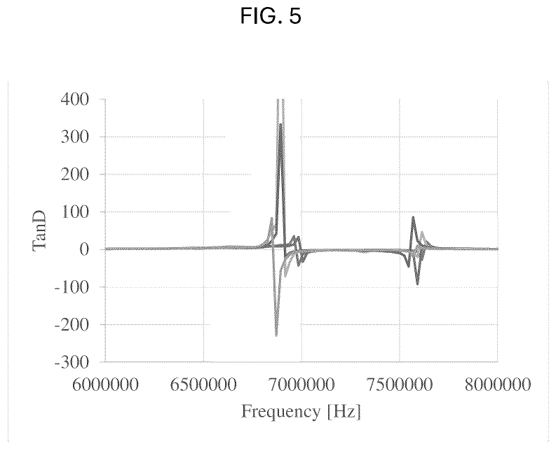

FIG. 6(a) and FIG. 6(b) are waveform diagrams when the resistive components of impedances between pairs of electrodes at a resonant frequency of piezoelectric elements according to the embodiment are measured, wherein FIG. 6(a) is a waveform diagram when micro-PZT piezoelectric ceramics are used as the piezoelectric elements and FIG. 6(b) is a waveform diagram when milli-PZT piezoelectric ceramics are used as the piezoelectric elements.

### DETAILED DESCRIPTION OF THE PREFERRED EMBODIMENTS

Hereinafter, a crack detection device for a piezoelectric element according to an embodiment of the present invention will be specifically described with reference to the drawings. Note that in the following description, when directions up, down, left, and right are indicated, it shall mean up, down, left, and right when viewed from the front of the figure.

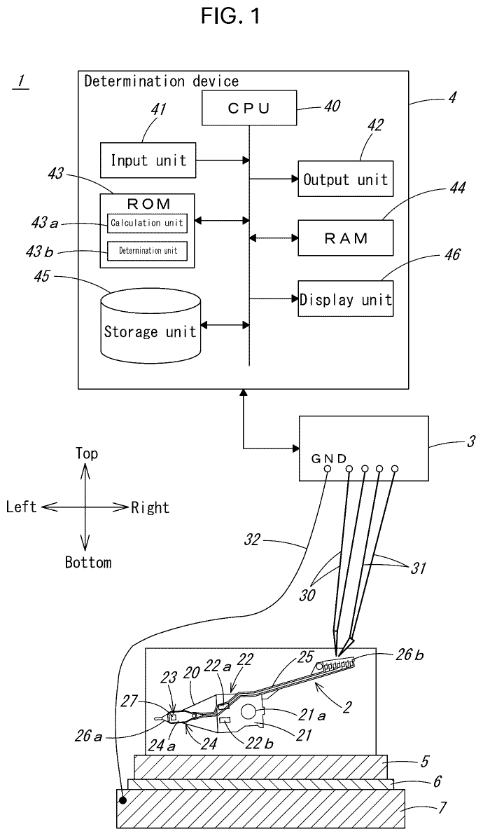

A crack detection device 1 for a piezoelectric element shown in FIG. 1 can detect a crack in the piezoelectric element by measuring the resistive component of an impedance between a pair of electrodes provided in the piezoelectric element. To describe this point more specifically, the crack detection device 1 for the piezoelectric element shown in FIG. 1 is mainly composed of an HDD suspension 2, which is an object to be measured, an impedance analyzer 3, and a determination device 4. Hereinafter, each component will be described in detail.

The HDD suspension 2 has a configuration similar to that of the conventional one, and as shown in FIG. 1, mainly includes a load beam 20 as a driven member, a base plate 21 as a base portion, and a piezoelectric element 22. The load beam 20 applies a load onto a head portion 23 on a distal end side (left side in the figure) shown in FIG. 1, and is made of, for example, a thin metal plate such as stainless steel having a spring property. As shown in FIG. 1, a flexure 24 as a wiring member is attached to the load beam 20.

As shown in FIG. 1, the flexure 24 is formed by forming a wiring pattern 25 on a conductive thin plate 24a such as a thin rolled stainless steel plate having a spring property via an electrical insulating layer. The wiring pattern 25 is composed of a wiring portion for signal transmission and a wiring portion for power supply. The wiring pattern 25 has both ends provided with terminal portions 26a and 26b as shown in FIG. 1.

On the other hand, as shown in FIG. 1, a slider 27 provided in the head portion 23 is supported on a distal end side (left side in the figure) of the flexure 24, and the slider 27 is conductively connected to the terminal portion 26a on one end side (left side in the figure) of the wiring pattern 25.

On the other hand, as shown in FIG. 1, the load beam 20 has a proximal end side (right side in the figure) supported by the base plate 21. As shown in FIG. 1, the base plate 21 is provided with a substantially circular boss portion 21a. The base plate 21 is attached to a carriage side (not shown) via the boss portion 21a and is rotationally driven by a voice coil motor. The piezoelectric element 22 is provided between the base plate 21 and the load beam 20, as shown in FIG. 1.

The piezoelectric element 22 is made of piezoelectric ceramics such as lead zirconate titanate (PZT) and includes a pair of electrodes 22a and 22b as shown in FIG. 1. In the present embodiment, the presence or absence of a crack in the piezoelectric element 22 is detected by measuring the resistive component of an impedance between the pair of electrodes 22a and 22b of the single piezoelectric element 22.

Thus, the HDD suspension 2, which is an object to be measured, configured as described above is placed on a measurement table 5 having a horizontally long rectangular shape in cross section as shown in FIG. 1 for measurement. As shown in FIG. 1, an insulating material 6 having a horizontally long rectangular shape in cross section is provided on the under surface of the measurement table 5, and a base 7 of equipment having a horizontally long rectangular shape in cross section is provided on the under surface of the insulating material 6.

The impedance analyzer 3 can measure the resistive component of the impedance between the pair of electrodes 22a and 22b of the single piezoelectric element 22 described above. Specifically, as shown in FIG. 1, the impedance analyzer 3 has a measurement signal output side connected with two first measurement cables 30 and a measurement signal reception side connected with two second measurement cables 31. The first measurement cables 30 and the second measurement cables 31 are connected to the terminal portion 26b on the other end side (right side in the figure) of the wiring pattern 25 described above. As a result, a measurement voltage at a frequency according to the setting can be applied from the impedance analyzer 3 to the HDD suspension 2, which is an object to be measured, via the first measurement cables 30. In this way, a resonant-frequency voltage can be applied to the piezoelectric element 22 described above by the impedance analyzer 3.

Meanwhile, when the resonant-frequency voltage is applied to the piezoelectric element 22 as described above, the impedance analyzer 3 can receive and measure the resistive component of the impedance between the pair of electrodes 22a and 22b at the resonant frequency of the piezoelectric element 22 via the second measurement cables 31. The measured value of the resistive component of the impedance is then output to the determination device 4 shown in FIG. 1. As shown in FIG. 1, the impedance analyzer 3 is connected with a ground cable 32, and the ground cable 32 is connected to the base 7.

The determination device 4 is composed of a personal computer (PC) or the like, and as shown in FIG. 1, is composed of a CPU 40, an input unit 41 capable of inputting predetermined data to the determination device 4, an output unit 42 capable of outputting predetermined data outside the determination device 4, a ROM 43 composed of a writable flash ROM, etc., storing a predetermined application program or the like, a RAM 44 functioning as a work area, a buffer memory, or the like, a storage unit 45 composed of a hard disk, etc., and a display unit 46 composed of a liquid crystal display (LCD), etc.

Thus, since the predetermined application program is stored in the ROM 43, the determination device 4 thus configured is provided with a calculation unit 43a and a determination unit 43b as functional blocks. The calculation unit 43a calculates a determination value for the measured value of the resistive component of the impedance measured by the impedance analyzer 3. The determination unit 43b then determines whether a crack has occurred in the piezoelectric element 22 depending on whether the determination value calculated by the calculation unit 43a is equal to or greater than a threshold value stored in advance in the storage unit 45. This point will be described in detail by describing a usage example of the crack detection device 1 for the piezoelectric element.

Thus, the crack detection device 1 for the piezoelectric element configured as described above first sets a threshold value. Specifically, for a plurality of HDD suspensions 2, the impedance analyzers 3 are used to apply the resonant-frequency voltage to the piezoelectric elements 22 and receive and measure the resistive components of the impedances between the pairs of electrodes 22a and 22b at the resonant frequency of the piezoelectric elements 22, as described above. The measured values of the resistive components of the impedances are then output to the determination device 4 shown in FIG. 1. In response to this, the calculation unit 43a of the determination device 4 calculates the determination values using Formula 5 below.

$$P = F ( xi , ai ) \qquad Formula 5$$

Here, P represents the determination value, i represents the number of measurement points of the resistive components of the impedances between the pairs of electrodes 22a and 22b at the resonant frequency of the piezoelectric elements 22, and xi represents the measured value at each measurement point. As a result, the calculation unit 43a calculates the determination value using the above Formula 5 for the measured value at each measurement point of the resistive components of the impedances output from the impedance analyzers 3. At this time, F(xi, ai) is an arbitrary function, and ai is an arbitrary set coefficient. Therefore, the coefficient ai is input in advance using the input unit 41 of the determination unit 4 shown in FIG. 1 and is stored in the storage unit 45.

Thus, the calculation unit 43a uses the above Formula 5, that is, weights the measured value at each measurement point of the resistive components of the impedances output from the impedance analyzers 3 by the arbitrary set coefficient ai, and calculates the determination value. A threshold value is then set for the calculated determination values. When the threshold value is input using the input unit 41 of the determination device 4 shown in FIG. 1, the threshold value is stored in the storage unit 45 by the CPU 40.

Thus, if the threshold value is set in this manner, the determination unit 43b determines whether the determination value calculated by the calculation unit 43a is equal to or greater than the threshold value stored in advance in the storage unit 45. If the determination value is equal to or greater than the threshold value, it is determined that no crack has occurred in the piezoelectric element 22, and if the determination value is not equal to or greater than the threshold value, it is determined that a crack has occurred in the piezoelectric element 22. This makes it possible to detect a crack in the piezoelectric element without optical observation in the same manner as in the conventional art.

Here, the above content will be described in more detail by making the above Formula 5 into a more specific formula. That is, the calculation unit 43a can use Formula 6 shown below as Formula 5.

$$F = \sum ( xi * ai ) \qquad Formula 6$$

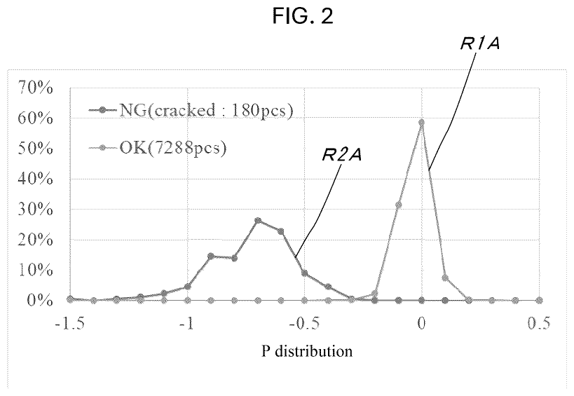

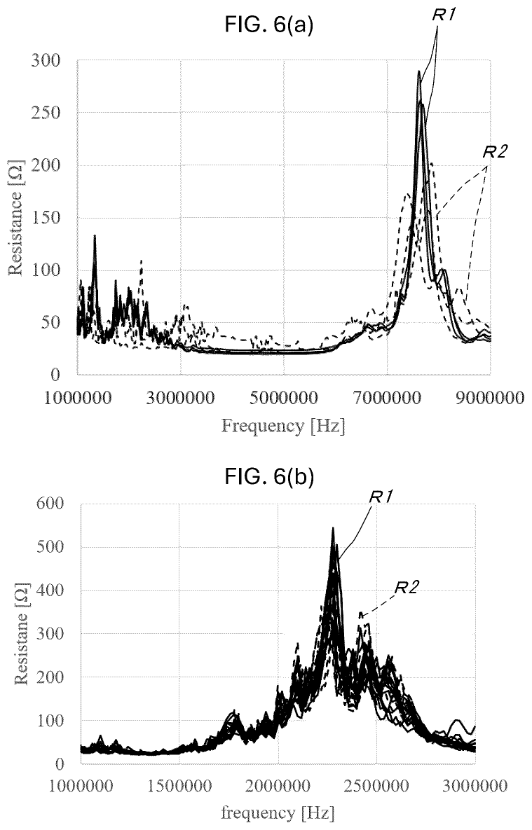

To describe this point using a specific example, the calculation unit 43a calculates the determination values using the above Formula 6 for the measurement results shown in FIG. 6(b). Thus, the calculated determination values are shown in the graph shown in FIG. 2. A waveform RIA shown in FIG. 2 indicates that no cracks have occurred in the piezoelectric elements 22, and a waveform R2A indicates that cracks have occurred in the piezoelectric elements 22. Therefore, unlike FIG. 6(b), there is a clear difference. Accordingly, “−0.3” can be set as the threshold value, whereby the determination unit 43b determines whether the determination value calculated by the calculation unit 43a is equal to or greater than the threshold value (−0.3) stored in advance in the storage unit 45. The determination unit 43b determines that no crack has occurred in the piezoelectric element 22 if the determination value is equal to or greater than the threshold value (−0.3) and determines that a crack has occurred in the piezoelectric element 22 if the determination value is not equal to or greater than the threshold value (−0.3). As a result, even if there may be no place where a clear difference occurs between the waveform R1 group and the waveform R2 group as shown in FIG. 6(b), a clear difference can be made by calculation using the calculation unit 43a. This makes it easy to set the threshold value, so that the possibility of erroneous detection can be reduced during implementation operation.

However, the distribution of the determination values shown in FIG. 2 has the waveform R1A and the waveform R2A adjacent to each other, so that depending on variations in the piezoelectric element 22 and the impedance analyzer 3, there is a possibility that the determination value is not equal to or greater than the threshold value (−0.3) even if no crack has occurred in the piezoelectric element 22. In this case, the determination unit 43b determines that a crack has occurred in the piezoelectric element 22, and thus, there is also the possibility of erroneous detection. Accordingly, the calculation unit 43a can also be configured to use Formula 7 shown below as Formula 5.

$$F ( bi , xi ) = \frac{1}{1 - {e}^{- \sum bi * xi}} \qquad Formula 7$$

Meanwhile, Formula 7 is referred to as a sigmoid function, and bi is an arbitrary set coefficient. Therefore, the coefficient bi is input in advance using the input unit 41 of the determination device 4 shown in FIG. 1 and is stored in the storage unit 45.

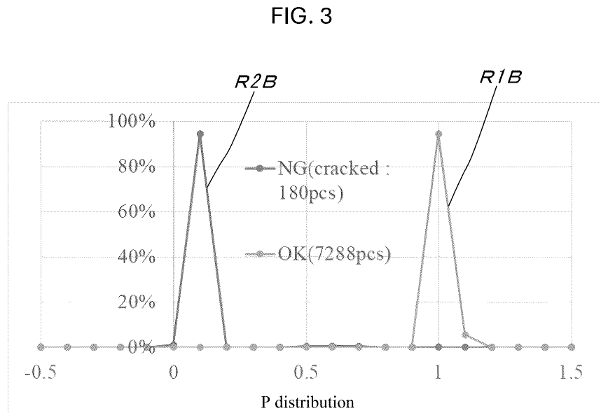

Thus, the calculation unit 43a calculates the determination values using the above Formula 7 for the measurement results shown in FIG. 6(b). The calculated determination values are shown in the graph shown in FIG. 3. A waveform RIB shown in FIG. 3 indicates that no cracks have occurred in the piezoelectric elements 22 and a waveform R2B indicates that cracks have occurred in the piezoelectric elements 22. Accordingly, unlike FIG. 6(b), there is a clear difference. Furthermore, the waveform R1B and the waveform R2B are not adjacent to each other as compared with FIG. 2, so that the possibility of erroneous detection due to variations in the piezoelectric element 22 and the impedance analyzer 3 can be reduced.

Thus, for the determination values calculated in this manner, for example, a portion located substantially in the middle between the waveform R1B and the waveform R2B shown in FIG. 3 can be set as the threshold value “0.5”. As a result, the determination unit 43b determines whether the determination value calculated by the calculation unit 43a is equal to or greater than the threshold value (0.5) stored in advance in the storage unit 45. The determination unit 43b then determines that no crack has occurred in the piezoelectric element 22 if the determination value is equal to or greater than the threshold value (0.5) and determines that a crack has occurred in the piezoelectric element 22 if the determination value is not equal to or greater than the threshold value (0.5). As a result, even if there may be no place where a clear difference occurs between the waveform R1 group and the waveform R2 group as shown in FIG. 6(b), a clear difference can be made by calculation using the calculation unit 43a. This makes it easy to set the threshold value, so that the possibility of erroneous detection can be reduced during implementation operation. Furthermore, the waveform R1B and the waveform R2B are not adjacent to each other, so that the possibility of erroneous detection due to variations in the piezoelectric element 22 and the impedance analyzer 3 can be reduced.

Therefore, as described above, by having the calculation unit 43a calculate the determination values using a formula related to Formula 5, the possibility of erroneous detection can be reduced regardless of the type of piezoelectric element.

Meanwhile, for a method of setting the coefficients ai and bi described above, the coefficients can be set by calculation using a statistical method such as a least squares method or a maximum likelihood method by accumulating samples with known presence or absence of cracks in the piezoelectric elements 22 and measurement data thereof. According to such a statistical method, if the data to be analyzed and the method are the same, the coefficients are uniquely determined. Therefore, even in the case of a piezoelectric element 22 where a waveform change is difficult to confirm as shown in FIG. 6(b), accurate detection can be confirmed without depending on the skill or awareness of an engineer.

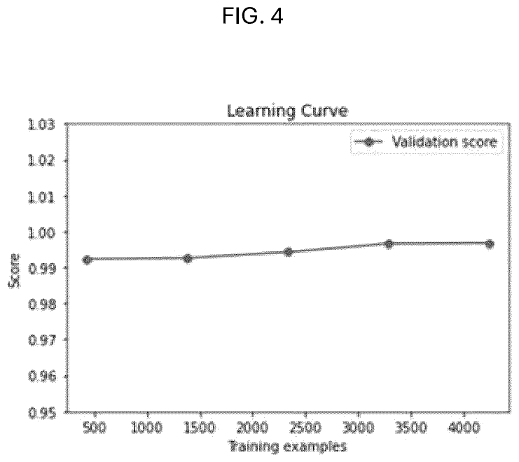

To describe this point using a specific example, when Formula 7 is used and the coefficient bi is set using a value calculated by the maximum likelihood method, the results of comparing the number of samples used for analysis and the accuracy of detection are as shown in FIG. 4. That is, as shown in FIG. 4, the validation score improves as the number of data points to be analyzed (the number of samples) increases. As a result, it has been confirmed that the accuracy of detection improves as the number of data points to be analyzed (the number of samples) increases.

Accordingly, if the coefficients ai and bi described above are set using values calculated by a statistical method, accurate detection can be performed.

Note that the shapes and the like shown in the present embodiment are merely examples, and various modifications and changes can be made within the scope of the gist of the present invention described in the claims. For example, the HDD suspension 2 has been described as an example in the present embodiment, but the present invention is not limited thereto and can be applied to any type of piezoelectric element.

Further, in the present embodiment, an example has been shown in which it is determined whether a crack has occurred in the piezoelectric element 22 based on whether the determination value calculated by the calculation unit 43a is equal to or greater than the threshold value stored in advance in the storage unit 45. However, the present invention is not limited thereto, and it may be determined whether a crack has occurred in the piezoelectric element 22 based on whether the determination value calculated by the calculation unit 43a is equal to or smaller than the threshold value stored in advance in the storage unit 45.

What is claimed:

1. A crack detection method for a piezoelectric element, comprising the steps of:
applying a resonant-frequency voltage to a piezoelectric element;
measuring a resistive component of an impedance between a pair of electrodes of the piezoelectric element alone due to the application of the voltage;
calculating a determination value for a measured value of the measured resistive component of the impedance by using the following equation (Formula (1)):
$$P = F ( xi , ai )$$
where P represents the determination value, i represents the number of measurement points, xi represents a measured value at each of the measurement points, ai represents an arbitrary set coefficient, and F(xi, ai) represents an arbitrary function consisting of xi and ai; and
taking the calculated determination value into consideration and determining whether a crack has occurred in the piezoelectric element based on a preset threshold value.

2. The crack detection method for the piezoelectric element according to claim 1, wherein the determination value is calculated using the following formula (Formula (2)) as the Formula (1):
$$F = \sum ( x * ai )$$

3. The crack detection method for the piezoelectric element according to claim 1, wherein the determination value is calculated using a sigmoid function expressed by the following formula (Formula (3)) as the Formula (1):
$$F ( bi , xi ) = \frac{1}{1 - {e}^{- \sum bi * xi}}$$
where bi represents an arbitrary set coefficient.

4. A crack detection device for a piezoelectric element, comprising:
a voltage application means operable to apply a resonant-frequency voltage to a piezoelectric element;
a measurement means operable to measure a resistive component of an impedance between a pair of electrodes of the piezoelectric element alone due to the application of the voltage;
a calculation means operable to calculate a determination value for a measured value of the measured resistive component of the impedance by using the following formula (Formula (4)):
$$P = F ( xi , ai )$$
where P represents the determination value, i represents the number of measurement points, xi represents a measured value at each of the measurement points, ai represents an arbitrary set coefficient, and F(xi, ai) represents an arbitrary function consisting of xi and ai; and
a determination means that takes the calculated determination value into consideration and determines whether a crack has occurred in the piezoelectric element based on a preset threshold value.
